(19) United States
(12) Patent Application Publication
(10) Pub. No.: US 2026/0093862 A1
(43) Pub. Date: Apr. 2, 2026

(54) INTEGRATED METHOD FOR SUPPORTING COMPLEX SYSTEM DESIGN AND OPTIMIZATION

(71) Applicants: Beihang University, Beijing (CN); Hangzhou International Innovation Institute of Beihang University, Hangzhou (CN)

(72) Inventors: Lin Zhang, Hangzhou (CN); Pengfei Gu, Hangzhou (CN); Zhuoyi Wu, Beijing (CN); Zhen Chen, Hangzhou (CN); Yuteng Zhang, Hangzhou (CN)

(21) Appl. No.: 19/342,752

(22) Filed: Sep. 29, 2025

(30) Foreign Application Priority Data
Sep. 29, 2024 (CN) 2024113668344

(51) Int. Cl. G06F 30/15

(52) U.S. Cl. CPC G06F 30/15

(57) ABSTRACT

An integrated method for supporting complex system design and optimization selects first graphical-textual model frameworks in a problem domain; implements functional requirement verification in a validation domain and guides a physical architecture model; selects second graphical-textual model frameworks in a solution domain to establish a physical architecture model; generates an integrated simulation model oriented towards functional and non-functional requirements in the validation domain; selects third graphical-textual model frameworks in an optimization domain to establish a multidisciplinary optimization model, and establishes binding with preset subsystem parameters in the physical architecture model of the solution domain and output values of variables related to an objective function; automatically feeds an optimal optimization scheme obtained through iterative solving based on intelligent optimization algorithms to a system design model for automatic verification. The integrated method breaks down barriers between models of various stages, improves the development efficiency, and avoids the difficulty of seamless integration.

### CROSS-REFERENCE TO RELATED APPLICATION

This application claims priority to Chinese patent application No. CN 202411366834.4, filed to China National Intellectual Property Administration (CNIPA) on Sep. 29, 2024, which is herein incorporated by reference in its entirety.

### TECHNICAL FIELD

The disclosure relates to the field of system modeling technologies, and more particularly to an integrated method for supporting complex system design and optimization.

### BACKGROUND

With the continuous improvement of science, technology, and requirements, especially in the military and manufacturing fields, the complexity of research objects is gradually increasing. Traditional document-based systems engineering methods have brought great difficulties and challenges to modelers. With the rapid development of computer technology, model-based systems engineering (MBSE) has gradually become a mainstream method for complex systems and even systems of systems in the field of system design and simulation modeling. A model-based development mode has many advantages such as reusability, unambiguity, case of understanding, and ease of reuse. Currently, a mainstream modeling language for MBSE is systems modeling language (SysML). Based on the SysML, it is a preferred scheme to realize the unification of a full-process modeling of complex systems from requirement analysis to system design, system simulation and system optimization.

At current, the main method for full-process modeling of complex systems is as follows. First, 9 types of diagrams (requirement diagrams, block definition diagrams, internal block diagrams, state machine diagrams, etc.) provided by the SysML are used to complete requirement and system design modeling of the complex system. Then, re-modeling and simulating are performed through other simulation modeling languages such as Modelica, MATLAB/Simulink, and then combining with optimization software such as Isight, ModelCenter to achieve system optimization.

The current full-process modeling methods for complex systems cannot unify the design modeling, simulation modeling, and optimization modeling of complex systems, requiring different modeling languages and platforms to be implemented. This greatly increases the learning cost for modelers, and furthermore, the cross-language and cross-platform implementation method makes it difficult to change the complex system model design process and cannot guarantee consistency.

### SUMMARY

In view of this, the disclosure provides an integrated method for supporting complex system design and optimization to solve the problems in the background.

To achieve the above purpose, the disclosure adopts the following technical solutions.

Specifically, an integrated method for supporting complex system design and optimization, including:
dividing a model hierarchy according to modeling requirements into a problem domain, a solution domain, a validation domain, and an optimization domain;
selecting a first graphical model framework and a first textual model framework preset and consistent with a meta-model in the problem domain to sequentially complete requirement analysis, functional analysis, and logical architecture model establishment of a system;
automatically generating, in the validation domain, a logical simulation model oriented towards functional requirements through a XLab interpreter and a simulator preset to realize validation of the functional requirements and provide guidance for a physical architecture model;
selecting a second graphical model framework and a second textual model framework preset and consistent with the meta-model in the solution domain to establish the physical architecture model of the system;
automatically generating, in the validation domain, an integrated simulation model oriented towards the functional requirements and non-functional requirements through the XLab interpreter and the simulator;
selecting, in the optimization domain, a third graphical model framework and a third textual model framework preset and consistent with the meta-model to establish a multidisciplinary optimization model, and the multidisciplinary optimization model being configured to describe a multidisciplinary optimization object model of a complex system; and establishing binding with subsystem parameters preset in the physical architecture model of the solution domain and output values of variables related to an objective function; and
automatically feeding an optimal optimization scheme obtained based on an intelligent optimization algorithm to a system design model through the optimization domain to achieve automatic verification of top-level requirements.

The method are applied during the design and development phase of complex products such as electric vehicles, and can be extended to fields including aerospace, automotive, and shipbuilding. Taking electric vehicles as an example, the optimal parameter combination output from the optimization domain (e.g., motor power, battery capacity, transmission ratio) is automatically written into the system design model via the XLab interpreter, thereby updating the model parameters and initiating an adaptive simulation for verification. This feedback mechanism significantly improves design efficiency. On one hand, it avoids manual parameter tuning and shortens iteration cycles. On the other hand, it ensures consistency between optimization results and the system model, reducing errors caused by model fragmentation. The final deliverables include: an updated system design model solution (including optimal parameters); an optimization report (including objective function convergence curves and Pareto front plots); and a list of performance metrics verified through simulation (e.g., 8% increase in range, 0.4-second reduction in acceleration time), which can be directly used for design validation.

In an embodiment, in the above integrated method for supporting complex system design and optimization, the logical architecture model includes: a requirement model framework, a use case model framework, an activity model framework, a coupled class model framework, and a discrete class model framework.

The requirement model framework is configured to describe needs of stakeholders, system design requirements, and a relationship between the needs of stakeholders and the system design requirements.

The use case model framework is configured to describe functional scenarios of the complex system.

The activity model framework is configured to describe a sequence of functional activities to realize the functional scenarios of the complex system.

The coupled class model framework is configured to describe a model in the complex system composed of atomic models or other coupled class model components.

The discrete class model framework is configured to describe an indivisible model with discrete behavior in the complex system.

In an embodiment, in the above integrated method for supporting complex system design and optimization, the first graphical model framework includes: a requirement graphical modeling framework, a use case graphical modeling framework, an activity graphical modeling framework, a coupled class graphical modeling framework, and a discrete class graphical modeling framework.

The requirement graphical modeling framework includes preset requirement diagrams.

The use case graphical modeling framework includes preset use case diagrams.

The activity graphical modeling framework includes preset activity diagrams.

The coupled class graphical modeling framework includes a combination of preset definition diagrams and preset connection diagrams.

The discrete class graphical modeling framework includes a combination of the preset definition diagrams and preset state machine diagrams.

The preset requirement diagrams are configured to describe stakeholders, needs of the stakeholders, system design requirements, and a relationship between the needs of the stakeholders and the system design requirements.

The preset use case diagrams are configured to describe the system, use cases of the system, participants, and relationships among the system, the use cases of the system, the participants.

The preset activity diagrams are configured to describe a functional activity interaction between the system and external units or between internal subsystems of the system.

The preset definition diagrams are configured to describe component parameters, state variables, and input and output port types of a system graphical model framework;

The preset connection diagrams are configured to describe connection relationships between components of a coupled class graphical model.

The preset state machine diagrams are configured to describe behavioral constraint relationships represented by state transitions between different states of a discrete class graphical model.

In an embodiment, in the above integrated method for supporting complex system design and optimization, the first textual model framework includes: a requirement textual modeling framework, a use case textual modeling framework, an activity textual modeling framework, a coupled class textual modeling framework, and a discrete class textual modeling framework.

The requirement textual modeling framework includes preset requirement texts.

The use case textual modeling framework includes preset use case texts.

The activity textual modeling framework includes preset activity texts.

The coupled class textual modeling framework includes a combination of preset definition texts and preset connection texts.

The discrete class textual modeling framework includes a combination of the preset definition texts and preset state machine texts.

The preset requirement texts are configured to describe stakeholders, needs of the stakeholders, system design requirements, and requirement relationships among the stakeholders, the needs of the stakeholders, the system design requirements.

The preset use case texts are configured to describe the system, use cases of the system, participants, and relationships among the system, the use cases of the system, the participants.

The preset definition texts are configured to describe component parameters, state variables, and input and output port types of a system textual model.

The preset connection texts are configured to describe connection relationships between components of a coupled class textual model.

The preset state machine texts are configured to describe behavioral constraint relationships represented by state transitions between different states of a discrete class textual model.

In an embodiment, in the above integrated method for supporting complex system design and optimization, the physical architecture model framework includes: a coupled class model framework, a continuous class model framework, and a discrete class model framework.

The coupled class model framework is configured to describe a model in the complex system composed of atomic models or other coupled class model components.

The continuous class model framework is configured to describe an indivisible model with continuous behavior in the complex system.

The discrete class model framework is configured to describe an indivisible model with discrete behavior in the complex system.

In an embodiment, in the above integrated method for supporting complex system design and optimization, the second graphical model framework includes: a coupled class graphical modeling framework, a continuous class graphical modeling framework, and a discrete class graphical modeling framework.

The coupled class graphical modeling framework includes a combination of preset definition diagrams and preset connection diagrams;

The continuous class graphical modeling framework includes a combination of preset definition diagrams and preset equation diagrams; and

The discrete class graphical modeling framework includes a combination of preset definition diagrams and preset state machine diagrams;

The preset definition diagrams are configured to describe component parameters, state variables, and input and output port types of a system graphical model framework;

The preset connection diagrams are configured to describe connection relationships between components of a coupled class graphical model;

The preset equation diagrams are configured to describe behavioral constraint relationships represented by ordinary differential and algebraic differential equations in a continuous class graphical model; and

The preset state machine diagrams are configured to describe behavioral constraint relationships represented by state transitions between different states of a discrete class graphical model.

In an embodiment, in the above integrated method for supporting complex system design and optimization, the second textual model framework includes: a coupled class textual modeling framework, a continuous class textual modeling framework, and a discrete class textual modeling framework.

The coupled class textual modeling framework includes a combination of preset definition texts and preset connection texts.

The continuous class textual modeling framework includes a combination of preset definition texts and preset equation texts.

The discrete class textual modeling framework includes a combination of preset definition texts and preset state machine texts.

The definition texts are configured to describe component parameters, state variables, and input and output port types of various models.

The connection texts are configured to describe connection relationships between components of a coupled model.

The equation text texts are configured to describe behavioral constraint relationships represented by ordinary differential and algebraic differential equations in a continuous class textual model.

The state machine texts are configured to describe behavioral constraint relationships represented by state transitions between different states of a discrete class textual model.

In an embodiment, in the above integrated method for supporting complex system design and optimization, the third graphical model framework includes: a multidisciplinary optimization class graphical model framework.

The multidisciplinary optimization class graphical model framework includes preset definition diagrams; and the preset definition diagrams are configured to describe design variables, design constraints, and optimization objectives in a multidisciplinary optimization graphical model.

In an embodiment, in the above integrated method for supporting complex system design and optimization, the third textual model framework includes: a multidisciplinary optimization class textual model framework.

The multidisciplinary optimization class textual model framework includes preset definition texts; and the preset definition texts are configured to describe design variables, design constraints, and optimization objectives in the multidisciplinary optimization textual model.

In an embodiment, in the above integrated method for supporting complex system design and optimization, the optimal optimization scheme is obtained through the intelligent optimization algorithms comprising a multi-objective genetic algorithm non-dominated sorting genetic algorithm II (NSGA-II).

Through the above technical solutions, compared with the related art, the disclosure provides the integrated method for supporting complex system design and optimization. In the problem domain, the preset graphical and textual model frameworks are used to sequentially complete the system requirement analysis, functional analysis, and logical architecture model establishment. Subsequently, in the validation domain, the logical simulation model oriented towards functional requirements is automatically generated through the interpreter and the simulator to realize the validation of the functional requirements and provide guidance for the physical architecture model. In the solution domain, the preset graphical and textual model frameworks are used to establish the physical architecture model. Subsequently, in the validation domain, the integrated simulation model oriented towards the functional requirements and non-functional requirements is automatically generated through the interpreter and the simulator. In the optimization domain, the preset graphical and textual model frameworks are used to establish the multidisciplinary optimization model and establish the binding with the subsystem parameters in the physical architecture model of the solution domain and the output values of variables related to the objective function. Finally, the optimal optimization scheme obtained through iterative solving based on the intelligent optimization algorithm is automatically fed back to the system design model through the optimization domain to achieve automatic verification of top-level requirements. Through a unified model representation method, the system design, simulation, and optimization of complex system models are integrated, breaking down the barriers between models of various stages, improving the efficiency of the complex system development process, and avoiding the difficulty of seamless integration between system optimization and system design and even simulation.

### BRIEF DESCRIPTION OF DRAWINGS

To make technical solutions of the disclosure clearer, the following briefly introduces the drawings required for description of embodiments or the related art. Apparently, the drawings described below are only some embodiments of the disclosure. For those skilled in the art, other drawings can be obtained based on these drawings without creative effort.

FIG. 1 illustrates a schematic diagram of an integrated method for supporting complex system design and optimization according to the disclosure.

FIGS. 2A-2B illustrate schematic diagrams of correspondence between graphical and textual requirement modeling frameworks. Specifically, FIG. 2A illustrates a schematic diagram of a requirement graphical modeling framework; and FIG. 2B illustrates a schematic diagram of a requirement textual modeling framework.

FIGS. 3A-3B illustrate schematic diagrams of correspondence between graphical and textual use case modeling frameworks. Specifically, FIG. 3A illustrates a schematic diagram of a use case graphical modeling framework; and FIG. 3B illustrates a schematic diagram of a use case textual modeling framework.

FIGS. 4A-4B illustrate schematic diagrams of correspondence between graphical and textual activity modeling frameworks. Specifically, FIG. 4A illustrates a schematic diagram of an activity graphical modeling framework; and FIG. 4B illustrates a schematic diagram of an activity textual modeling framework.

FIGS. 5A-5C illustrate schematic diagram of correspondence between graphical and textual coupled class modeling frameworks. Specifically, FIG. 5A illustrates a schematic diagram of a coupled class graphical modeling framework (definition diagram); FIG. 5B illustrates a schematic diagram of the coupled class graphical modeling framework (connection diagram); and FIG. 5C illustrates a schematic diagram of a coupled class textual modeling framework.

FIGS. 6A-6C illustrate schematic diagrams of correspondence between graphical and textual discrete class modeling frameworks. Specifically, FIG. 6A illustrates a schematic diagram of a discrete class graphical modeling framework (definition diagram); FIG. 6B illustrates a schematic diagram of the discrete class graphical modeling framework (state machine diagram); and FIG. 6C illustrates a schematic diagram of the discrete class textual modeling framework.

FIGS. 7A-7C illustrate schematic diagrams of correspondence between graphical and textual continuous modeling frameworks. Specifically, FIG. 7A illustrates a schematic diagram of a continuous class graphical modeling framework (definition diagram); FIG. 7B illustrates a schematic diagram of the continuous class graphical modeling framework (equation diagram); and FIG. 7C illustrates a schematic diagram of a continuous class textual modeling framework.

FIGS. 8A-8B illustrate schematic diagrams of correspondence between graphical and textual multidisciplinary optimization class model frameworks. Specifically, FIG. 8A illustrates a schematic diagram of a multidisciplinary optimization class graphical model framework; and FIG. 8B illustrates a schematic diagram of a multidisciplinary optimization class textual model framework.

### DETAILED DESCRIPTION OF EMBODIMENTS

In the following, technical solutions in the embodiments of the disclosure will be clearly and completely described with reference to the attached drawings. Apparently, the described embodiments are only a part of the embodiments of the disclosure, not all of the embodiments. Based on the embodiments in the disclosure, all other embodiments obtained by ordinary technicians in the field without creative labor belong to the scope of protection of the disclosure.

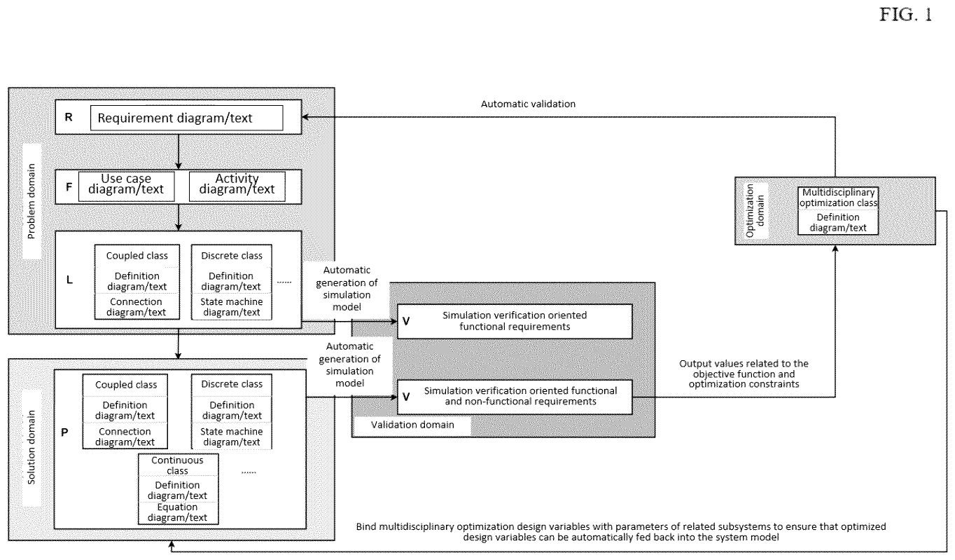

An embodiment of the disclosure discloses an integrated method for supporting complex system design and optimization. As shown in FIG. 1, the system design, simulation and optimization of complex system models are integrated through a unified model representation method, which breaks down barriers between models in various stages, improves the efficiency of the complex system development process, and avoids the difficulty of seamless integration between system optimization and system design and even simulation.

Specific steps of the integration method are as follows.
(1) A first graphical model framework and a first textual model framework preset and consistent with a meta-model are selected in a problem domain to sequentially complete requirement analysis, functional analysis, and logical architecture model establishment of a system.

Specifically, the logical architecture model includes: a requirement model framework, a use case model framework, an activity model framework, a coupled class model framework, and a discrete class model framework.

The requirement model framework is configured to describe needs of stakeholders, system design requirements, and a relationship between the needs of stakeholders and the system design requirements.

The use case model framework is configured to describe functional scenarios of the complex system.

The activity model framework is configured to describe a sequence of functional activities to realize the functional scenarios of the complex system.

The coupled class model framework is configured to describe a model in the complex system composed of atomic models or other coupled class model components.

The discrete class model framework is configured to describe an indivisible model with discrete behavior in the complex system.

In order to further optimize the above technical solution, the first graphical model framework includes: a requirement graphical modeling framework, a use case graphical modeling framework, an activity graphical modeling framework, a coupled class graphical modeling framework, and a discrete class graphical modeling framework.

The requirement graphical modeling framework includes preset requirement diagrams.

The use case graphical modeling framework includes preset use case diagrams.

The activity graphical modeling framework includes preset activity diagrams.

The coupled class graphical modeling framework includes a combination of preset definition diagrams and preset connection diagrams.

The discrete class graphical modeling framework includes a combination of the preset definition diagrams and preset state machine diagrams.

Specifically, the preset requirement diagrams are configured to describe stakeholders, needs of the stakeholders, system design requirements, and a relationship between the needs of the stakeholders and the system design requirements. The preset use case diagrams are configured to describe the system, use cases of the system, participants, and relationships among the system, the use cases of the system, the participants. The preset activity diagrams are configured to describe a functional activity interaction between the system and external units or between internal subsystems of the system. The preset definition diagrams are configured to describe component parameters, state variables, and input and output port types of a system graphical model framework. The preset connection diagrams are configured to describe connection relationships between components of a coupled class graphical model. The preset state machine diagrams are configured to describe behavioral constraint relationships represented by state transitions between different states of a discrete class graphical model.

In order to further optimize the above technical solution, the first textual model framework includes: a requirement textual modeling framework, a use case textual modeling framework, an activity textual modeling framework, a coupled class textual modeling framework, and a discrete class textual modeling framework.

The requirement textual modeling framework includes preset requirement texts.

The use case textual modeling framework includes preset use case texts.

The activity textual modeling framework includes preset activity texts.

The coupled class textual modeling framework includes a combination of preset definition texts and preset connection texts.

The discrete class textual modeling framework includes a combination of the preset definition texts and preset state machine texts.

Specifically, the preset requirement texts are configured to describe stakeholders, needs of the stakeholders, system design requirements, and requirement relationships among the stakeholders, the needs of the stakeholders, the system design requirements. The preset use case texts are configured to describe the system, use cases of the system, participants, and relationships among the system, the use cases of the system, the participants. The preset definition texts are configured to describe component parameters, state variables, and input and output port types of a system textual model. The preset connection texts are configured to describe connection relationships between components of a coupled class textual model. The preset state machine texts are configured to describe behavioral constraint relationships represented by state transitions between different states of a discrete class textual model.
(2) In a validation domain, a logical simulation model oriented towards functional requirements is automatically generated through a XLab interpreter and a simulator preset to realize validation of the functional requirements and provide guidance for a physical architecture model.

Specifically, the XLab interpreter and the XLab simulator are specifically as follows.

The XLab interpreter is used to generate cpp files (also known as C++ source code file) from the logical architecture model of the system.

The XLab simulator is used to compose all generated cpp files into a cpp engineering simulation project that conforms to discrete event system specification (DEVS) architecture.
(3) A second graphical model framework and a second textual model framework preset and consistent with the meta-model are selected in the solution domain to establish the physical architecture model of the system.

Specifically, the physical architecture model includes: a coupled class model framework, a continuous class model framework, and a discrete class model framework.

The coupled class model framework is configured to describe a model in the complex system composed of atomic models or other coupled class model components.

The continuous class model framework is configured to describe an indivisible model with continuous behavior in the complex system.

The discrete class model framework is configured to describe an indivisible model with discrete behavior in the complex system.

In order to further optimize the above technical solution, the second graphical model framework includes: a coupled class graphical modeling framework, a continuous class graphical modeling framework, and a discrete class graphical modeling framework.

The coupled class graphical modeling framework includes a combination of preset definition diagrams and preset connection diagrams.

The continuous class graphical modeling framework includes a combination of preset definition diagrams and preset equation diagrams.

The discrete class graphical modeling framework includes a combination of preset definition diagrams and preset state machine diagrams.

Specifically, preset definition diagrams are configured to describe component parameters, state variables, and input and output port types of a system graphical model framework. The preset connection diagrams are configured to describe connection relationships between components of a coupled class graphical model. The preset equation diagrams are configured to describe behavioral constraint relationships represented by ordinary differential and algebraic differential equations in a continuous class graphical model. The preset state machine diagrams are configured to describe behavioral constraint relationships represented by state transitions between different states of a discrete class graphical model.

In order to further optimize the above technical solution, the second textual model framework includes: a coupled class textual modeling framework, a continuous class textual modeling framework, and a discrete class textual modeling framework.

The coupled class textual modeling framework includes a combination of preset definition texts and preset connection texts.

The continuous class textual modeling framework includes a combination of preset definition texts and preset equation texts.

The discrete class textual modeling framework includes a combination of preset definition texts and preset state machine texts.

Specifically, the preset definition texts are configured to describe component parameters, state variables, and input and output port types of various models. The preset connection texts are configured to describe connection relationships between components of a coupled model. The preset equation text texts are configured to describe behavioral constraint relationships represented by ordinary differential and algebraic differential equations in a continuous class textual model. The preset state machine texts are configured to describe behavioral constraint relationships represented by state transitions between different states of a discrete class textual model.
(4) In the validation domain, an integrated simulation model oriented towards the functional requirements and non-functional requirements is automatically generated through the XLab interpreter and the simulator.

Specifically, the XLab interpreter and the XLab simulator are specifically as follows.

The XLab interpreter is used to generate the cpp files from the logical architecture model of the system.

The XLab simulator is used to compose all generated cpp files into a cpp engineering simulation project that conforms to DEVS architecture.
(5) In the optimization domain, a third graphical model framework and a third textual model framework preset and consistent with the meta-model are selected to establish a multidisciplinary optimization model. A binding with subsystem parameters preset in the physical architecture model of the solution domain and output values of variables related to an objective function is established. Finally, an optimal optimization scheme obtained by iterative solution based on an intelligent optimization algorithm is automatically fed back to a system design model through the optimization domain to achieve automatic verification of top-level requirements.

Specifically, the multidisciplinary optimization model framework is used to describe a multidisciplinary optimization object model of a complex system.

In order to further optimize the above technical solution, the third graphical model framework includes: a multidisciplinary optimization class graphical model framework.

The multidisciplinary optimization class graphical model framework includes preset definition diagrams.

Further, the following are the general steps to obtain the optimal optimization scheme based on the intelligent optimization algorithm such as multi-objective genetic algorithm NSGA-II.

### 1. Problem Definition

The objective function of the optimization problem is determined. Multiple objective functions that need to be optimized simultaneously are specified, such as minimizing cost, maximizing performance, etc. Decision variables are defined: the decision variables in the problem, namely the parameters that can be adjusted, are identified. Constraint conditions are determined: if constraint conditions exist, these conditions are specified to limit the range of feasible solutions.

### 2. Algorithm Initialization

### Population Initialization

An initial population is randomly generated, where each individual in the population represents a set of values for the decision variables.

The encoding method for individuals is selected according to the characteristics of the problem, such as binary encoding, real-number encoding, etc.

### 3. Non-Dominated Sorting

The objective function values of each individual are calculated.

The non-dominated sorting is performed on the population as follows.

First, all non-dominated individuals (i.e., individuals for which no other individual is superior in all objectives) are identified and assigned to the first front (non-dominated front).

Then, the remaining individuals are processed to find the next set of non-dominated individuals, which are assigned to the second front, and so on.

### 4. Congestion Calculation

The congestion for each individual within every non-dominated front is calculated.

The congestion reflects the density of solutions surrounding an individual and is obtained by computing the differences between neighboring individuals across each objective function.

Individuals with larger congestions indicate that the solutions around them are sparse and thus have a higher probability of being retained during selection.

### 5. Selection, Crossover and Mutation:

### Select Operation

Suitable individuals are selected to form the parent population based on non-dominated sorting and congestion.

Common selection methods include tournament selection, roulette wheel selection, etc.

### Cross Operation

Offspring individuals are generated by applying crossover to parent individuals.

The crossover method is chosen according to the problem characteristics, such as single-point crossover, multi-point crossover, etc.

### Mutation Operation

The offspring individuals are mutated to increase the diversity of the population.

Mutation involves random perturbations to certain decision variables of an individual.

### 6. Iterative Optimization

The offspring population and the parent population are combined to form a new population.

Steps including non-dominated sorting, congestion calculation, selection, crossover, and mutation are repeated until the termination criterion is met.

The termination criterion is satisfied when the maximum number of iterations is reached, or when the objective function values converge.

### 7. Result Analysis

The final non-dominated front obtained is regarded as a set of Pareto-optimal solutions.

A most suitable solution is selected from the Pareto-optimal solutions as the optimal optimization scheme according to specific problem requirements.

For example, the selection is made based on the decision-maker's preferences or practical application requirements.

When implementing NSGA-II algorithm, programming languages such as C++ are used to implement each step. At the same time, adjustments and optimizations are made according to the specific optimization problem, such as tuning algorithm parameters, selecting appropriate encoding schemes and genetic operators, so that the algorithm's performance and solution quality are improved.

Specifically, the preset definition diagrams are configured to describe design variables, design constraints, and optimization objectives in a multidisciplinary optimization graphical model.

In order to further optimize the above technical solution, the third textual model framework includes: a multidisciplinary optimization class textual model framework.

The multidisciplinary optimization class textual model framework includes preset definition texts.

Specifically, the preset definition texts are configured to describe design variables, design constraints, and optimization objectives in the multidisciplinary optimization textual model.

The following will be further explained with specific embodiments.

First of all, in the problem domain, a specific complex system object is modeled graphically by modelers according to a graphical model framework (i.e., first graphical model framework). The graphical model framework includes two classes and six kinds of diagrams, the two classes include a coupling class and a discrete class, and the six kinds of diagrams include requirement diagrams, use case diagrams, activity diagrams, definition diagrams, connection diagrams and state machine diagrams.

Graphical models are automatically generated from corresponding diagrams selected sequentially from the above-mentioned two classes and six types of diagrams, following the design methodology of requirements-function-logic-physical. The selection is made from preset graphical model framework, including the requirement graphical modeling framework, the use case graphical modeling framework, the activity graphical modeling framework, the coupled class graphical modeling framework, and the discrete class graphical modeling framework.

The requirement graphical modeling framework incudes: requirement diagrams, which are used to describe stakeholders, needs of the stakeholders, system design requirements, and a relationship between the needs of the stakeholders and the system design requirements

The use case graphical modeling framework includes: use case diagrams, which are used to describe the system, use cases of the system, participants, and relationships among the system, the use cases of the system, the participants.

The activity graphical modeling framework includes: activity diagrams, which are used to describe a functional activity interaction between the system and external units or between internal subsystems of the system.

The coupled class graphical modeling framework includes: definition diagrams and connection diagrams, which are used to describe a coupled model in the complex system, where the definition diagrams define the hierarchical structure of the coupled model and the connection diagrams define the connection relationships between components.

The discrete class graphical modeling framework includes: the definition diagrams and state machine diagrams, which are used to describe an indivisible model with discrete behavior in the complex system, where the definition diagrams define relevant parameters, state variables, input and output ports, etc. of the discrete class model, and the state machine diagrams define discrete behavior constraints of the discrete class model with state definition, transformation logic, etc.

According to the preset textual model framework (i.e., first textual model framework), the two classes and six kinds of diagrams are automatically converted into corresponding textual models. The requirement diagrams are processed textually to obtain textual models of the requirement diagrams. The use case diagrams are processed textually to obtain textual models of the use case diagrams. The activity diagrams are processed textually to obtain textual models of the activity diagrams. The definition diagrams and the connection diagrams are processed textually to obtain textual models for the coupled class. The definition diagrams and the state machine diagrams are processed textually to obtain textual models of the discrete class.

The preset textual model framework includes: requirement texts, use case texts, activity texts, definition texts, connection texts and state machine texts. The requirement texts are used to describe stakeholders, needs of the stakeholders, system design requirements, and requirement relationships among the stakeholders, the needs of the stakeholders, the system design requirements. The use case texts are used to describe the system, use cases of the system, participants, and relationships among the system, the use cases of the system, the participants. The activity texts are used to describe a functional activity interaction between the system and external units or subsystems within the system. The definition texts are used to describe component parameters, state variables, and input and output port types of the system textual model. The connection texts are used to describe connection relationships between components of the coupled class textual model. The state machine texts are used to describe behavioral constraint relationships represented by state transitions between different states of the discrete class textual model.

According to the preset textual model framework, the textual model is obtained, and the requirement diagrams, the use case diagrams, the activity diagrams, the definition diagrams, the connection diagrams and the state machine diagrams correspond to the requirement texts, the use case texts, the activity texts, the definition texts, the connection texts and the state machine texts respectively. The textual model is automatically generated according to the contents of the requirement texts, the use case texts, the activity texts, the definition texts, the connection texts and the state machine texts.

The textual model of coupled class and discrete class will be interpreted as C++ code by the interpreter to run logic simulation under the DEVS simulator.

In the validation domain, the logical simulation model generated by the problem domain will be simulated and verified according to the functional requirements.

In the solution domain, the modeler will guide the development of the physical architecture model according to the logical architecture model in the problem domain. A specific complex system object is modeled graphically by the modeler according to a graphical model framework (i.e., second graphical model framework). The graphical model framework includes three classes and four kinds of graphs, three classes include the coupled class, the continuous class and the discrete classes, and four kinds of diagrams include definition diagrams, connection diagrams, equation diagrams and state machine diagrams.

Graphical models are automatically generated from corresponding diagrams selected sequentially from the above-mentioned three classes and four types of diagrams, following the design methodology of requirements-function-logic-physical. The selection is made from preset graphical model framework, including the coupled class graphical modeling framework, the continuous class graphical modeling framework and the discrete class graphical modeling framework.

The coupled class graphical modeling framework includes: definition diagrams and connection diagrams, which are used to describe the coupled model in the complex system, where the definition diagrams define the hierarchical structure of the coupled model and the connection diagrams define the connection relationships between components.

The continuous class graphical modeling framework includes: definition diagrams and equation diagrams, which are used to describe an indivisible model with continuous behavior in the complex system, where the definition diagrams define relevant parameters, state variables, input and output ports, etc. of the continuous class model, and the equation diagrams define continuous behavior constraints of the continuous class model by ordinary differential/algebraic differential equations.

The discrete class graphical modeling framework includes: definition diagrams and state machine diagrams, which are used to describe an indivisible model with discrete behavior in the complex system, where the definition diagrams define relevant parameters, state variables, input and output ports, etc. of the discrete class model, and the state machine diagrams define discrete behavior constraints of the discrete class model with state definition, transformation logic, etc.

According to the preset textual model framework (i.e., second textual model framework), three types and four kinds of diagrams are automatically converted into corresponding textual models. The definition diagrams and the connection diagrams are textually processed to obtain textual models of the coupled class. The definition diagrams and the equation diagrams are textually processed to obtain the textual models of the continuous class. The definition diagrams and the state machine diagrams are textually processed to obtain the textual models of the discrete class.

The preset textual model framework includes definition texts, connection texts, equation texts and state machine texts. The definition texts are used to describe component parameters, state variables and input and output port types of the models. The connection texts are used to describe the connection relationships between the components of the coupled model. The equation texts are used to describe the behavior constraint relationship represented by ordinary differential/algebraic differential equations of the continuous class model. The state machine texts are used to describe the behavior constraint relationships represented by different states and state transitions between the different states.

According to the preset textual model framework (i.e., second textual model framework), a textual model is obtained, and the definition diagrams, the connection diagrams, the equation diagrams and the state machine diagrams correspond to the definition texts, the connection texts, the equation texts and the state machine texts respectively. The textual model is automatically generated according to the contents of the definition texts, the connection texts, equation texts and the state machine texts.

Textual models of the coupled class, the continuous class and the discrete classes will be interpreted as C++ code by the interpreter to run the whole system simulation under the DEVS simulator.

In the validation domain, the physical simulation model generated by the solution domain will carry out collaborative simulation verification for functional and non-functional requirements, and output variable values related to the optimization objective function.

In the optimization domain, the modeler will define the multidisciplinary optimization model of the system according to the physical architecture model in the solution domain. The modeler carries out graphical modeling on the multidisciplinary optimization object according to the graphical model framework (i.e., third graphical model framework), and the graphical model framework includes definition diagrams.

The modeler will automatically generate the corresponding graphical model for the definition diagrams. In the preset graphical model framework, the preset graphical model framework includes the multidisciplinary optimization class graphical model framework.

The multidisciplinary optimization class graphical model framework includes: definition diagrams, which are used to describe design variables, design constraints and optimization objectives in the multidisciplinary optimization graphical model.

According to the preset textual model framework (i.e., third textual model framework), the definition diagram is textually processed to obtain the multidisciplinary optimization class textual model framework.

The preset textual model framework includes: definition texts, and the definition texts are used to describe system design variables, design constraints and optimization objectives.

According to the preset textual model framework, the textual model is obtained, the definition diagrams are corresponding to the definition texts respectively, and the textual model is automatically generated according to the content of the definition texts.

The design variables of the optimization class will be bound to the parameters of the subsystem through the connection diagrams of the coupled class.

The textual model of multidisciplinary optimization class will be sent to the self-defined intelligent optimization algorithm for iterative solution, and the optimal optimization scheme will be automatically fed back to the system design model through the binding of optimization domain, and the top-level requirements can be automatically verified.

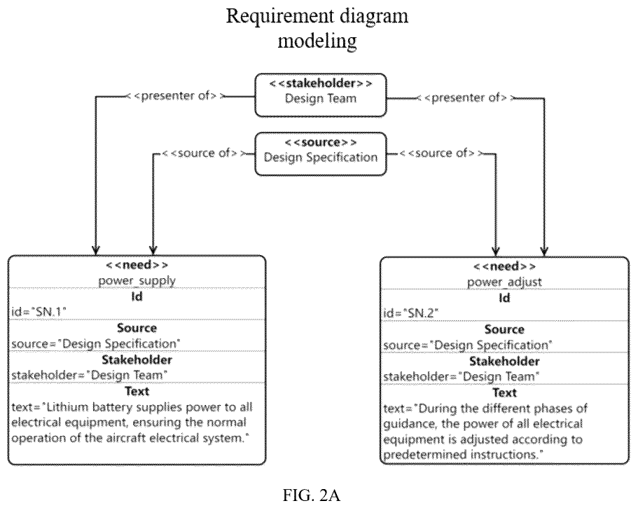

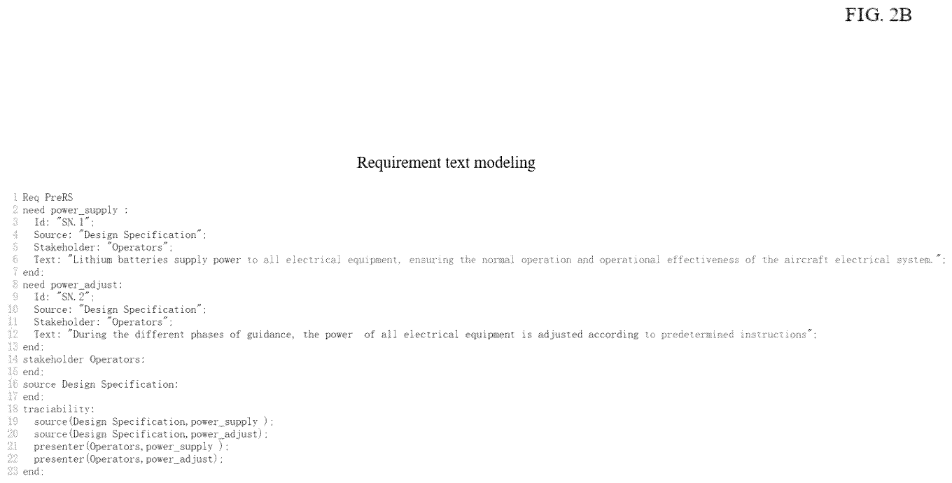

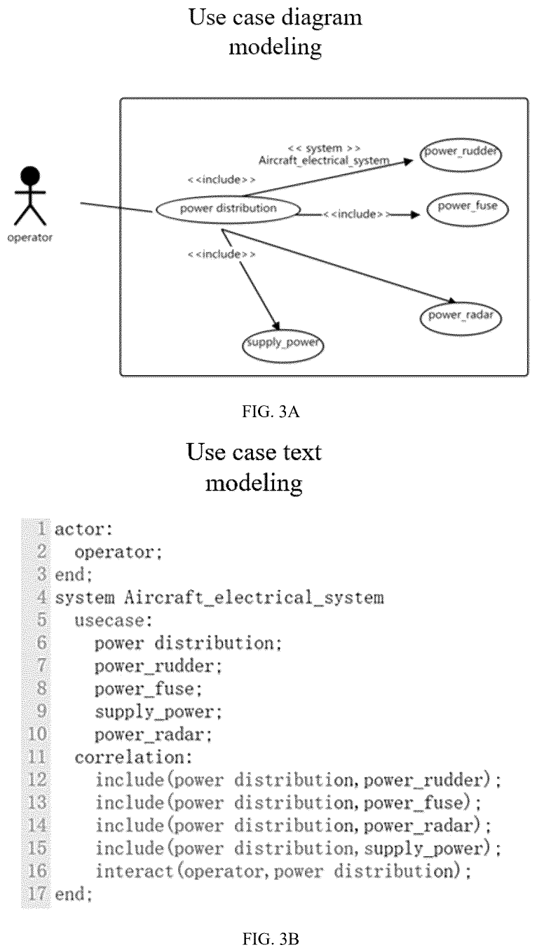

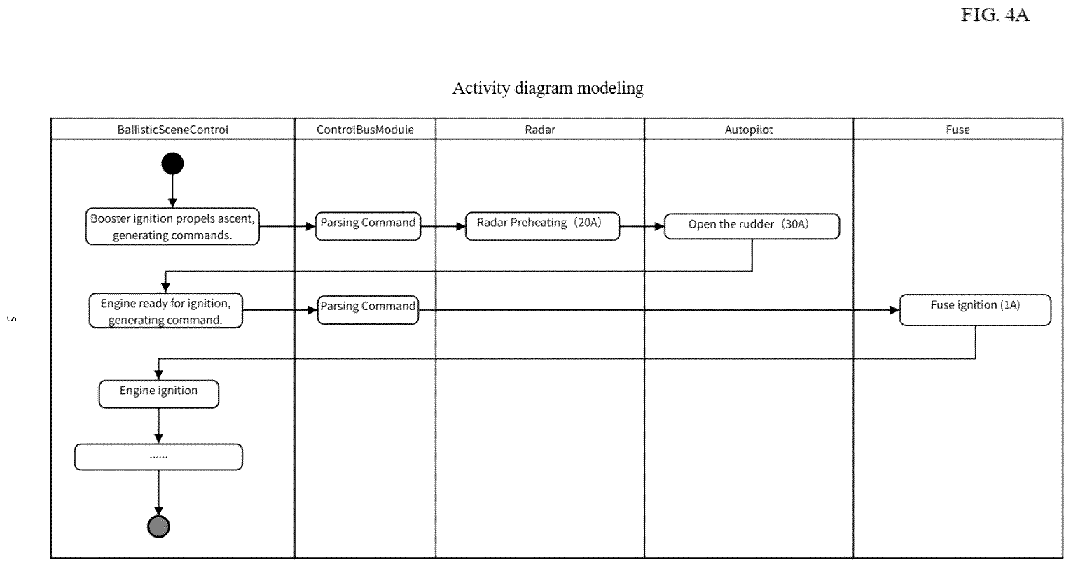

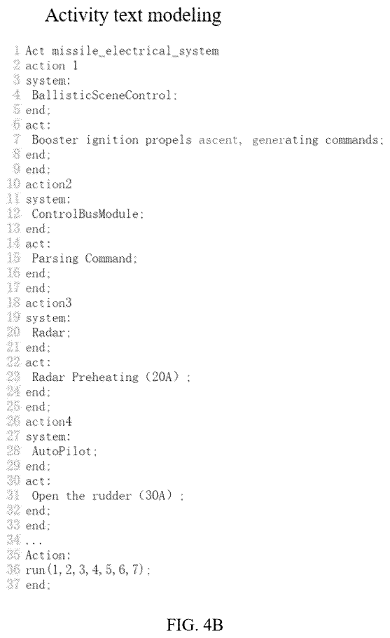

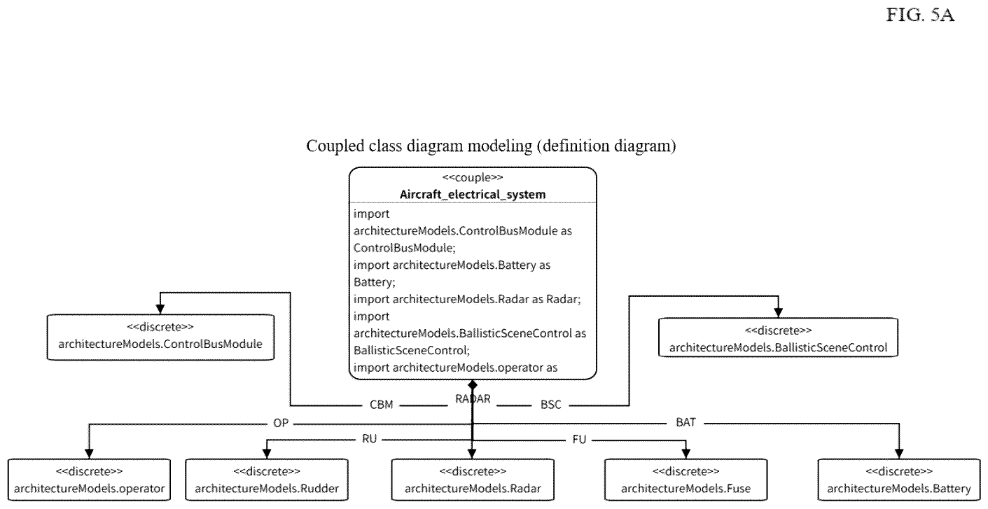

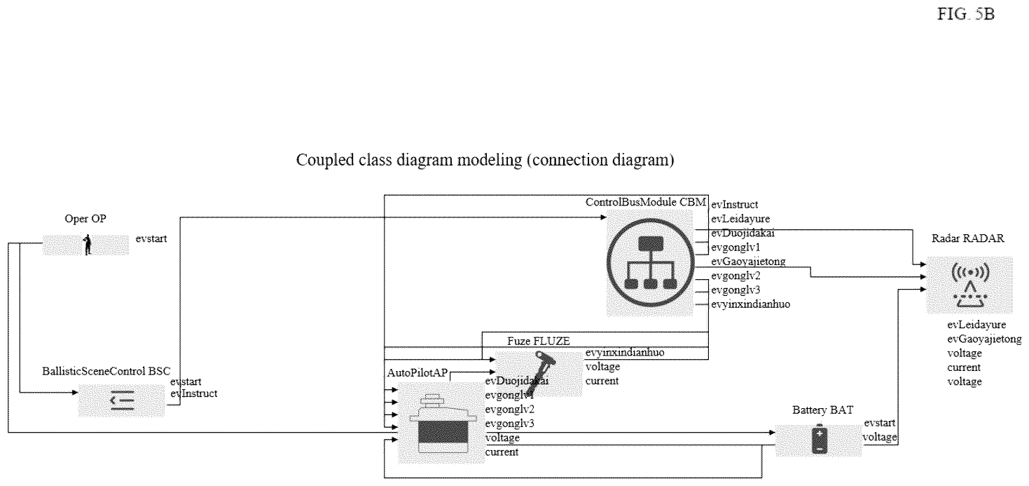

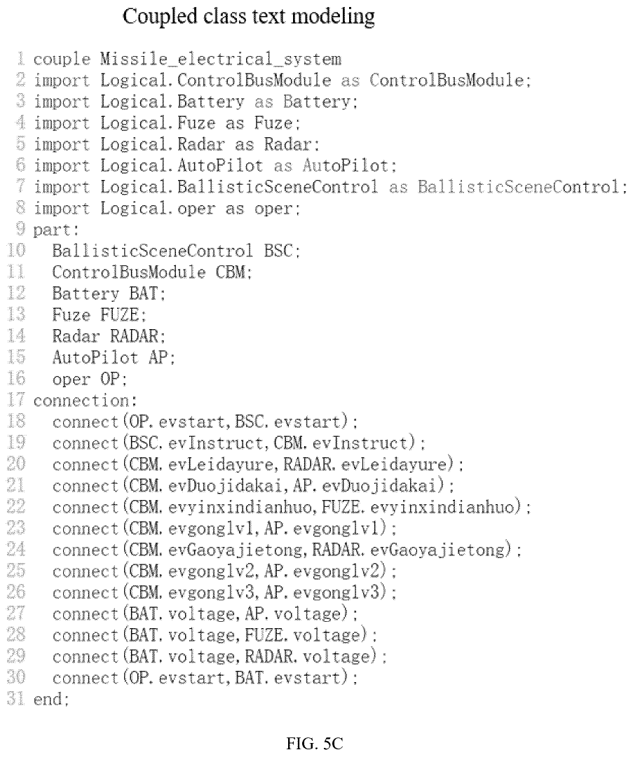

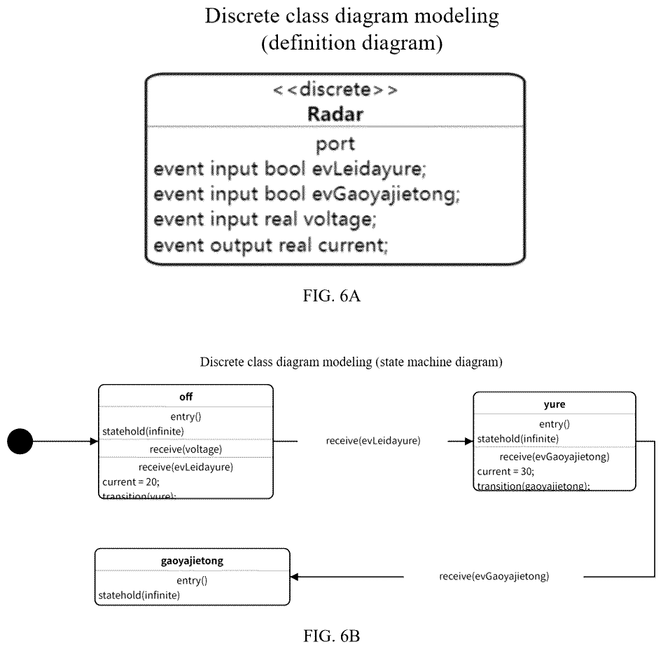

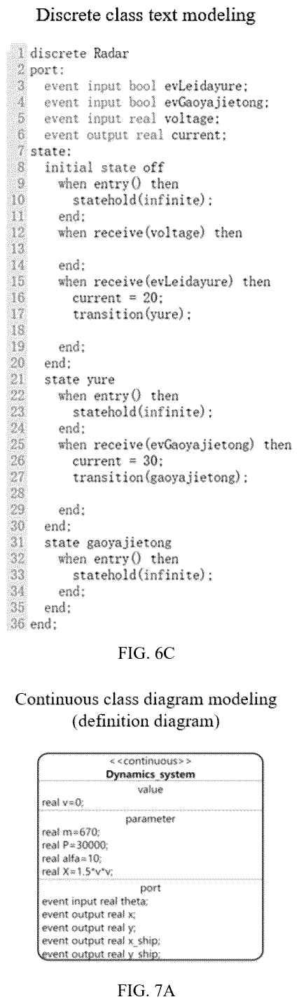

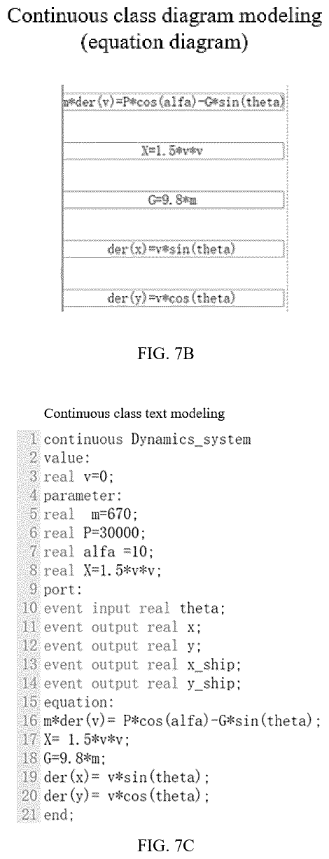

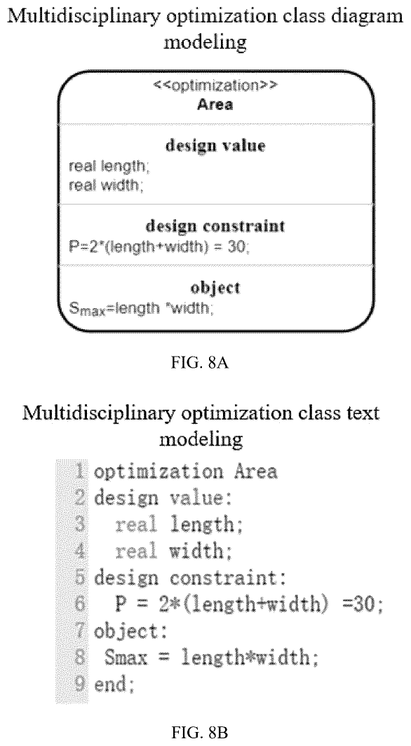

As shown in FIG. 2A to FIG. 8B, the requirement diagrams in the requirement graphical modeling framework correspond to the requirement texts in the requirement textual modeling framework, which are used to define the stakeholders, needs of the stakeholders, the system design requirements and the relationship between the needs of the stakeholders and the system design requirements.

The use case diagrams in the use case graphical modeling framework correspond to the use case texts in the use case textual modeling framework, which are used to define the system, the use case of the system, the participants and the relationships among the system, the use cases of the system, the participants.

The activity diagrams in the activity diagram graphical modeling framework correspond to the activity texts in the activity diagram textual modeling framework, which are used to define the functional activity interaction between the system and the external units or the subsystems within the system.

The definition diagrams in the coupled class graphical modeling framework correspond to the definition texts in the coupled class textual modeling framework, which are used to define the hierarchical structure information of the coupled class model, including structural characteristics such as components, references and ports. The connection diagrams in the coupled class graphical modeling framework correspond to the connection texts in the coupled class textual modeling framework, which are used to define the connection relationships between the components of the coupled class model.

The definition diagrams in the discrete class graphical modeling framework correspond to the definition texts in the discrete class textual modeling framework, which are used to define the structural information of the discrete class model, including instantiation parameters, state variables, references, ports and other structural characteristics. The state machine diagrams in the discrete class graphical modeling framework correspond to the state machine texts in the discrete class textual modeling framework, so as to define the discrete behavior constraint relationship of the discrete class model based on event-triggered state transition.

The definition diagrams in the continuous class graphical modeling framework correspond to the definition texts in the continuous class textual modeling framework, which are used to define the structural information of the continuous class model, including instantiation parameters, state variables, references, ports and other structural characteristics. The equation diagrams in the continuous class graphical modeling framework correspond to the equation texts in the continuous class textual modeling framework, and the continuous behavior constraint relationship of the continuous class model based on time continuous change is defined by ordinary differential/algebraic differential equations.

The definition diagrams in the multidisciplinary optimization class graphical model framework correspond to the definition texts in the multidisciplinary optimization class textual model framework, which are used to define system design variables, design constraints and optimization objectives.

Each embodiment in this specification is described in a progressive way, and each embodiment focuses on the differences from other embodiments, so it is only necessary to refer to the same and similar parts between each embodiment. As for a device disclosed in the embodiment, because it corresponds to the method disclosed in the embodiment, the description is relatively simple, and the relevant points can only be described in the method.

The above description of the disclosed embodiments enables those skilled in the art to make or use the disclosure. Many modifications to these embodiments will be apparent to those skilled in the art, and the general principles defined herein can be implemented in other embodiments without departing from the spirit or scope of the disclosure. Therefore, the disclosure is not to be limited to the embodiments shown herein, but is to be accorded the widest scope consistent with the principles and novel features disclosed herein.

What is claimed is:

1. An integrated method for supporting complex system design and optimization, comprising:
dividing a model hierarchy according to modeling requirements into a problem domain, a solution domain, a validation domain, and an optimization domain;
selecting a first graphical model framework and a first textual model framework preset and consistent with a meta-model in the problem domain to sequentially complete requirement analysis, functional analysis, and establishment of a logical architecture model of a system;
automatically generating, in the validation domain, a logical simulation model oriented towards functional requirements through a XLab interpreter and a simulator preset to realize validation of the functional requirements and provide guidance for a physical architecture model;
selecting a second graphical model framework and a second textual model framework preset and consistent with the meta-model in the solution domain to establish the physical architecture model of the system;
automatically generating, in the validation domain, an integrated simulation model oriented towards the functional requirements and non-functional requirements through the XLab interpreter and the simulator;
selecting, in the optimization domain, a third graphical model framework and a third textual model framework preset and consistent with the meta-model to establish a multidisciplinary optimization model, and the multidisciplinary optimization model being configured to describe a multidisciplinary optimization object model of a complex system; and establishing binding with subsystem parameters preset in the physical architecture model of the solution domain and output values of variables related to an objective function; and
automatically feeding an optimal optimization scheme obtained based on an intelligent optimization algorithm to a system design model through the optimization domain to achieve automatic verification of top-level requirements.

2. The integrated method for supporting complex system design and optimization as claimed in claim 1, wherein the logical architecture model comprises:
a requirement model framework, a use case model framework, an activity model framework, a coupled class model framework, and a discrete class model framework; wherein:
the requirement model framework is configured to describe needs of stakeholders, system design requirements, and a relationship between the needs of stakeholders and the system design requirements;
the use case model framework is configured to describe functional scenarios of the complex system;
the activity model framework is configured to describe a sequence of functional activities to realize the functional scenarios of the complex system;
the coupled class model framework is configured to describe a model in the complex system composed of atomic models or other coupled class model components; and
the discrete class model framework is configured to describe an indivisible model with discrete behavior in the complex system.

3. The integrated method for supporting complex system design and optimization as claimed in claim 1, wherein the first graphical model framework comprises:
a requirement graphical modeling framework, a use case graphical modeling framework, an activity graphical modeling framework, a coupled class graphical modeling framework, and a discrete class graphical modeling framework; wherein:
the requirement graphical modeling framework comprises preset requirement diagrams;
the use case graphical modeling framework comprises preset use case diagrams;
the activity graphical modeling framework comprises preset activity diagrams;
the coupled class graphical modeling framework comprises a combination of preset definition diagrams and preset connection diagrams; and
the discrete class graphical modeling framework comprises a combination of the preset definition diagrams and preset state machine diagrams;
the preset requirement diagrams are configured to describe stakeholders, needs of the stakeholders, system design requirements, and a relationship between the needs of the stakeholders and the system design requirements;
the preset use case diagrams are configured to describe the system, use cases of the system, participants, and relationships among the system, the use cases of the system, the participants;
the preset activity diagrams are configured to describe a functional activity interaction between the system and external units or between internal subsystems of the system;
the preset definition diagrams are configured to describe component parameters, state variables, and input and output port types of a system graphical model framework;
the preset connection diagrams are configured to describe connection relationships between components of a coupled class graphical model; and
the preset state machine diagrams are configured to describe behavioral constraint relationships represented by state transitions between different states of a discrete class graphical model.

4. The integrated method for supporting complex system design and optimization as claimed in claim 1, wherein the first textual model framework comprises:
a requirement textual modeling framework, a use case textual modeling framework, an activity textual modeling framework, a coupled class textual modeling framework, and a discrete class textual modeling framework; wherein:
the requirement textual modeling framework comprises preset requirement texts;
the use case textual modeling framework comprises preset use case texts;
the activity textual modeling framework comprises preset activity texts;
the coupled class textual modeling framework comprises a combination of preset definition texts and preset connection texts; and
the discrete class textual modeling framework comprises a combination of the preset definition texts and preset state machine texts;
the preset requirement texts are configured to describe stakeholders, needs of the stakeholders, system design requirements, and requirement relationships among the stakeholders, the needs of the stakeholders, the system design requirements;
the preset use case texts are configured to describe the system, use cases of the system, participants, and relationships among the system, the use cases of the system, the participants;
the preset definition texts are configured to describe component parameters, state variables, and input and output port types of a system textual model;
the preset connection texts are configured to describe connection relationships between components of a coupled class textual model; and
the preset state machine texts are configured to describe behavioral constraint relationships represented by state transitions between different states of a discrete class textual model.

5. The integrated method for supporting complex system design and optimization as claimed in claim 1, wherein the physical architecture model framework comprises:
a coupled class model framework, a continuous class model framework, and a discrete class model framework; wherein:
the coupled class model framework is configured to describe a model in the complex system composed of atomic models or other coupled class model components;
the continuous class model framework is configured to describe an indivisible model with continuous behavior in the complex system; and
the discrete class model framework is configured to describe an indivisible model with discrete behavior in the complex system.

6. The integrated method for supporting complex system design and optimization as claimed in claim 1, wherein the second graphical model framework comprises:
a coupled class graphical modeling framework, a continuous class graphical modeling framework, and a discrete class graphical modeling framework; wherein:
the coupled class graphical modeling framework comprises a combination of preset definition diagrams and preset connection diagrams;
the continuous class graphical modeling framework comprises a combination of preset definition diagrams and preset equation diagrams; and
the discrete class graphical modeling framework comprises a combination of preset definition diagrams and preset state machine diagrams;
the preset definition diagrams are configured to describe component parameters, state variables, and input and output port types of a system graphical model framework;
the preset connection diagrams are configured to describe connection relationships between components of a coupled class graphical model;
the preset equation diagrams are configured to describe behavioral constraint relationships represented by ordinary differential and algebraic differential equations in a continuous class graphical model; and
the preset state machine diagrams are configured to describe behavioral constraint relationships represented by state transitions between different states of a discrete class graphical model.

7. The integrated method for supporting complex system design and optimization as claimed in claim 1, wherein the second textual model framework comprises:
a coupled class textual modeling framework, a continuous class textual modeling framework, and a discrete class textual modeling framework; wherein:
the coupled class textual modeling framework comprises a combination of preset definition texts and preset connection texts;
the continuous class textual modeling framework comprises a combination of preset definition texts and preset equation texts; and
the discrete class textual modeling framework comprises a combination of preset definition texts and preset state machine texts;
the preset definition texts are configured to describe component parameters, state variables, and input and output port types of various models;
the preset connection texts are configured to describe connection relationships between components of a coupled model;
the preset equation text texts are configured to describe behavioral constraint relationships represented by ordinary differential and algebraic differential equations in a continuous class textual model; and
the preset state machine texts are configured to describe behavioral constraint relationships represented by state transitions between different states of a discrete class textual model.

8. The integrated method for supporting complex system design and optimization as claimed in claim 1, wherein the third graphical model framework comprises: a multidisciplinary optimization class graphical model framework;
the multidisciplinary optimization class graphical model framework comprises preset definition diagrams; and the preset definition diagrams are configured to describe design variables, design constraints, and optimization objectives in a multidisciplinary optimization graphical model.

9. The integrated method for supporting complex system design and optimization as claimed in claim 1, wherein the third textual model framework comprises: a multidisciplinary optimization class textual model framework;
the multidisciplinary optimization class textual model framework comprises preset definition texts; and the preset definition texts are configured to describe design variables, design constraints, and optimization objectives in the multidisciplinary optimization textual model.

10. The integrated method for supporting complex system design and optimization as claimed in claim 1, wherein the optimal optimization scheme is obtained through the intelligent optimization algorithms comprising a multi-objective genetic algorithm non-dominated sorting genetic algorithm II (NSGA-II).
